(19) United States
(12) Patent Application Publication
(10) Pub. No.: US 2019/0252640 A1
(43) Pub. Date: Aug. 15, 2019

(54) FUNCTIONAL FILM AND ORGANIC EL ELEMENT

(71) Applicant: FUJIFILM Corporation, Tokyo (JP)

(72) Inventors: Kenichi KAKISHITA, Kanagawa (JP); Kyohisa UCHIUMI, Kanagawa (JP)

(73) Assignee: FUJIFILM Corporation, Tokyo (JP)

(21) Appl. No.: 16/393,255

(22) Filed: Apr. 24, 2019

Related U.S. Application Data
(63) Continuation of application No. PCT/JP2017/039947, filed on Nov. 6, 2017.

(30) Foreign Application Priority Data
Nov. 7, 2016 (JP) 2016-217054
Nov. 30, 2016 (JP) 2016-233006

(51) Int. Cl. H01L 51/52

(52) U.S. Cl. CPC H01L 51/5253

(57) ABSTRACT

Provided are a functional film that can exhibit high gas barrier properties by forming separate regions and an organic EL device. The functional film includes: a resin layer having impermeability to oxygen in which a plurality of recess portions are formed to be discretely disposed, in which a modulus of elasticity of the resin layer is 0.5 GPa to 10 GPa, and an oxygen permeability of the resin layer is 10 cc/(m²·day·atm) or lower.

### CROSS-REFERENCE TO RELATED APPLICATIONS

This application is a Continuation of PCT International Application No. PCT/JP2017/039947 filed on Nov. 6, 2017, which claims priority under 35 U.S.C. § 119(a) to Japanese Patent Application No. 2016-217054, filed on Nov. 7, 2016 and Japanese Patent Application No. 2016-233006, filed on Nov. 30, 2016. Each of the above applications is hereby expressly incorporated by reference, in its entirety, into the present application.

### BACKGROUND OF THE INVENTION

### 1. Field of the Invention

The present invention relates to a functional film and an organic EL element including the functional film.

### 2. Description of the Related Art

In various devices including an organic TFT, for example, a printable electronics (PE) sensor, an electronic device element, an organic solar cell, an optical element, a display device such as an liquid crystal display or an organic electroluminescence (EL) display, or various semiconductor devices, a gas barrier film such as a packaging material for packaging a portion or component requiring moisture resistance, a food product, an electronic component, a medical component, or the like is used.

Recently, in the field of organic devices (for example, an organic TFT device, an organic solar cell device, or an organic EL device), needs for a transparent gas barrier film as an alternative to a glass substrate have increased. The transparent gas barrier film is lightweight and advantageous in costs because a roll-to-roll method is applicable thereto. However, the transparent gas barrier film has a problem in that water vapor barrier properties are poorer than those of a glass substrate.

In general, the gas barrier film has a configuration in which a gas barrier layer that exhibits gas barrier properties is formed on a plastic film such as a polyethylene terephthalate (PET) film as a support. In addition, as the gas barrier layer included in the gas barrier film, for example, layers formed of various inorganic compounds such as silicon nitride, silicon oxide, or aluminum oxide are known.

In order to form the inorganic layer formed of an inorganic compound, thin film formation using a vacuum deposition method such as sputtering or plasma chemical vapor deposition (CVD) is used.

In addition, depending on the use of the gas barrier film, not only excellent gas barrier properties but also various properties such as high transparency (high visible transmittance) or high oxidation resistance are required.

In particular, in a case where the gas barrier film is used in a device such as a liquid crystal display, an organic EL display, or a solar cell that needs to allow transmission of light, the gas barrier film needs to have high transparency.

As a configuration of the gas barrier film capable of obtaining higher gas barrier performance, an organic/inorganic lamination type gas barrier film (hereinafter, also referred to as “lamination type gas barrier film”) having a laminate structure in which an organic layer formed of an organic compound and an inorganic layer formed of an inorganic compound are alternately laminated on a support is known.

In the lamination type gas barrier film, by forming the inorganic layer on the organic layer as an underlayer, the surface where the inorganic layer is formed is smoothened by the organic layer, and the inorganic layer is formed on the organic layer having excellent smoothness. As a result, the uniform inorganic layer having no fractures, cracks, or the like is formed, and excellent gas barrier performance is obtained. In addition, by repeatedly providing a plurality of laminate structures in which the organic layer and the inorganic layer are laminated, higher gas barrier performance can be obtained.

For example, JP2013-031794A describes a functional film including: a support; an organic layer that is formed on the support; and an inorganic layer that is formed on the organic layer.

### SUMMARY OF THE INVENTION

Here, in a case where a flat gas barrier film is used in an organic device, the gas barrier film is bonded while bending the gas barrier film so as to conform (adhere) to the organic device and a substrate where the organic device is disposed. Therefore, there is a problem in that fracturing, cracking, or the like occurs and barrier performance is insufficient.

The present invention has been made under the above-described circumstances, and an object thereof is to provide a functional film that can exhibit high gas barrier properties by forming separate regions and an organic EL element including the same functional film.

The present inventors conducted a thorough investigation in order to achieve the object and found that the object can be achieved with a functional film including a resin layer having impermeability to oxygen in which a plurality of recess portions are formed to be discretely disposed, in which a modulus of elasticity of the resin layer is 0.5 GPa to 10 GPa, and an oxygen permeability of the resin layer is 10 cc/(m²·day·atm) or lower, thereby completing the present invention.

That is, the present inventors found that the object can be achieved with the following configurations.

(1) A functional film comprising:

a resin layer having impermeability to oxygen in which a plurality of recess portions are formed to be discretely disposed,

in which a modulus of elasticity of the resin layer is 0.5 GPa to 10 GPa, and

an oxygen permeability of the resin layer is 10 cc/(m²·day·atm) or lower.

The oxygen permeability can be measured using OX-TRAN 2/20 (manufactured by Mocon Inc.)

(2) The functional film according to (1), further comprising:

a substrate film that is formed on a surface of the resin layer opposite to a surface where the recess portions are formed.

(3) The functional film according to (2),

in which an oxygen permeability of the substrate film is 1 cc/(m²·day·atm) or lower.

(4) The functional film according to any one of (1) to (3),

in which at least an inorganic layer is foamed on the surface of the resin layer on the recess portion side.

(5) An organic EL element comprising:

the functional film according to any one of (1) to (4).

(6) The functional film according to any one of (1) to (4),

in which a curvature radius of a connection portion between a side surface and a bottom surface of the recess portion in the resin layer a curvature radius of a connection portion between the surface of the resin layer and the side surface of the recess portion are 5 μm to 200 μm.

(7) The functional film according to any one of (1) to (4) and (6),

in which a depth h of the recess portion in the resin layer is 1 μm to 100 μm,

a width t between recess portions adjacent to each other is 5 μm to 300 μm, and

an aspect ratio h/t of the depth h of the recess portion to the width t between recess portions adjacent to each other is lower than 3.0.

(8) The functional film according to any one of (1) to (4), (6), and (7),

in which the resin layer includes scattering particles.

(9) The functional film according to any one of (1) to (4) and (6) to (8),

in which the recess portion has a regular polygonal shape in a plan view.

According to the present invention, a functional film having high transparency that can exhibit high gas barrier properties by forming separate regions and an organic EL element can be provided.

### BRIEF DESCRIPTION OF THE DRAWINGS

FIG. 1 is a perspective view schematically illustrating an example of a functional film according to the present invention.

FIG. 2 is a cross-sectional view illustrating the functional film of FIG. 1.

FIG. 3 is a cross-sectional view schematically illustrating another example of the functional film according to the present invention.

FIG. 4 is a cross-sectional view schematically illustrating still another example of the functional film according to the present invention.

FIG. 5 is a cross-sectional view schematically illustrating still another example of the functional film according to the present invention.

FIG. 6 is a schematic cross-sectional view illustrating a curvature radius of a corner portion of a recess portion.

FIG. 7 is a cross-sectional view schematically illustrating an example of an organic EL element according to the present invention.

### DESCRIPTION OF THE PREFERRED EMBODIMENTS

Hereinafter, an embodiment of a functional film and an organic EL element according to the present invention will be described. In the drawings of this specification, dimensions of respective portions are appropriately changed in order to easily recognize the respective portions. In this specification, numerical ranges represented by “to” include numerical values before and after “to” as lower limit values and upper limit values.

In addition, in this specification, “(meth)acrylate” represents at least one or any one of acrylate or methacrylate. The same shall be applied to “(meth)acryloyl” or the like.

<Functional Film>

A functional film according to the embodiment of the present invention comprises a resin layer having impermeability to oxygen in which a plurality of recess portions are for formed to be discretely disposed, in which a modulus of elasticity of the resin layer is 0.5 GPa to 10 GPa, and an oxygen permeability of the resin layer is 10 cc/(m²·day·atm) or lower.

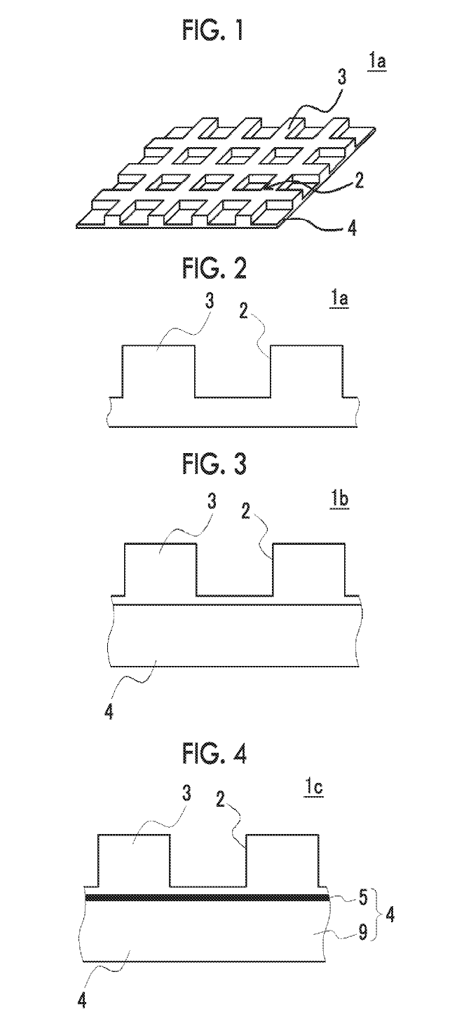

FIG. 1 is a perspective view schematically illustrating an example of the functional film according to the embodiment of the present invention, and FIG. 2 is a cross-sectional view of FIG. 1.

A functional film 1a illustrated in FIGS. 1 and 2 comprises a resin layer 3, and a plurality of recess portions 2 are formed to be discretely disposed on one surface of the resin layer 3.

A modulus of elasticity of the resin layer 3 is 0.5 GPa to 10 GPa, and an oxygen permeability of the resin layer 3 is 10 cc/(m²·day·atm).

A functional material, for example, an organic device can be disposed on the recess portions 2, and the functional material can be protected from moisture or oxygen by sealing the functional material with another glass substrate or another gas barrier film (not illustrated).

In this specification, “the recess portions being formed to be discretely disposed . . . on the film” represents that, as illustrated in FIG. 1, the recess portions 2 are independently disposed so as not to come into contact with each other in a two-dimensional direction along the film surface of the resin layer 3 in case of being observed (plan view) from a direction perpendicular to the film surface of the functional film. In the example illustrated in FIG. 1, the recess portions 2 have a quadrangular columnar shape, are independently present in the two-dimensional direction along the film surface of the functional film 1a in a state where they are surrounded by the resin layer 3 having impermeability to oxygen, and block permeation of oxygen into each of the recess portions 2 from the two-dimensional direction along the film surface of the functional film 1a.

In this specification, “having impermeability to oxygen” represents that the oxygen permeability is 10 cc/(m2·day·atm) or lower. The oxygen permeability of the resin layer having impermeability to oxygen is more preferably 1 cc/(m2·day·atm) or lower and still more preferably 10⁻¹ cc/(m²·day·atm) or lower. In this specification, “having impermeability” has the same definition as “having barrier properties”. That is, in this specification, a gas barrier refers to a barrier having impermeability to gas, and a water vapor barrier refers to a barrier having impermeability to water vapor. In addition, a layer having impermeability to oxygen and water vapor will be referred to as “barrier layer”.

As described above, according to the investigation by the present inventor, it was found that, in a case where a flat gas barrier film is used to seal an organic device, the gas barrier film is bonded while bending the gas barrier film so as to conform (adhere) to the organic device and a substrate where the organic device is disposed, and thus there is a problem in that fracturing, cracking, or the like occurs and barrier performance is insufficient.

On the other hand, the functional film according to the embodiment of the present invention comprises a resin layer having impermeability to oxygen in which a plurality of recess portions are formed to be discretely disposed, in which a modulus of elasticity of the resin layer is 0.5 GPa to 10 GPa, and an oxygen permeability of the resin layer is 10 cc/(m²·day·atm) or lower.

The functional film including the resin layer having barrier properties in which the recess portions are formed to be discretely disposed is disposed such that an organic device is disposed in the recess portions (refer to FIG. 7). As a result, it is not necessary to bond the gas barrier film while bending the gas barrier film, and fracturing, cracking, or the like can be suppressed.

As described above, the functional film according to the embodiment of the present invention comprises a resin layer having impermeability to oxygen in which a plurality of recess portions are formed to be discretely disposed, in which a modulus of elasticity of the resin layer is 0.5 GPa to 10 GPa, and an oxygen permeability of the resin layer is 10 cc/(m²·day·atm) or lower. As a result, it is not necessary to bond the gas barrier film while bending the gas barrier film, fracturing, cracking, or the like can be suppressed, and high gas barrier properties can be exhibited.

Here, in the functional film according to the embodiment of the present invention, in a case where a depth of the recess portions 2 in the resin layer 3 in which the recess portions 2 are disposed is represented by h and a width between recess portions 2 adjacent to each other, that is, a thickness of the resin layer 3 is represented by t, the depth h of the recess portions 2 in the resin layer 3 is preferably 1 μm to 100 μm, the width t between recess portions 2 adjacent to each other is preferably 5 μm to 300 μm, and an aspect ratio hit of the depth h to the width t between recess portions 2 adjacent to each other is preferably lower than 3.0.

The depth h of the recess portions formed in the resin layer 3 can be obtained by cutting the part of the recess portions in the functional film using a microtome to form a cross-section, observing this cross-section with an optical microscope, extracting 10 recess portions to measure depths, and obtaining an average value of the 10 depths.

In addition, the width t between recess portions 2 adjacent to each other (the thickness t of the resin layer 3) is the shortest distance between recess portions 2 adjacent to each other and can be calculated by observing one surface of the functional film using an optical microscope, extracting at least portions of the resin layer 3 between recess portions 2 adjacent to each other, reading widths of the 20 portions of the resin layer 3, and obtaining an average value thereof as the width t.

In addition, a ratio of the area of the recess portions 2 to the total area of the functional film in a plan view is calculated by observing the surface of the functional film from the top using a microscope, calculating a ratio (area of recess portions/geometric area) of the total area of the recess portions to the area (geometric area) of each of 30 mm×30 mm visual fields (five visual fields), and calculating the average value of the ratios in the respective visual fields (five visual fields).

In addition, the curvature radius of a corner portion of the recess portion 2 formed in the resin layer 3 is preferably 5 μm to 200 μm. Here, the curvature radius of a corner portion of the recess portion 2 refers to the curvature radius of a connection portion (represented by reference numeral 7 in FIG. 6) between a side surface and a bottom surface of the recess portion 2 in the resin layer 3 and the curvature radius of a connection portion (represented by reference numeral 8 in FIG. 6) between the surface of the resin layer 3 and the side surface of the recess portion 2.

By adjusting the curvature radius of a corner portion of the recess portion formed in the resin layer 3 to be 5 μm to 200 μm, an inorganic barrier layer or the like can be formed on the surface of the resin layer without defects, and deterioration in barrier properties can be suppressed.

The curvature radius of a corner portion of the recess portion can be obtained by cutting the part of the recess portions in the functional film using a microtome to form a cross-section, observing this cross-section with an optical microscope, extracting 10 recess portions to measure curvature radii, and obtaining an average value of the 10 curvature radii.

In addition, the functional film 1a illustrated in FIGS. 1 and 2 is configured to include only the resin layer 3, but the present invention is not limited thereto. As in a functional film 1b illustrated in FIG. 3, the resin layer 3 may be formed on a substrate film 4.

As illustrated in FIG. 3, the substrate film 4 is laminated on a surface of the resin layer 3 opposite to the surface where the recess portions 2 are formed.

Due to the presence of the substrate film 4, the strength of the functional film can be improved, and film formation can be easily performed.

It is preferable that the substrate film 4 has impermeability to oxygen, and the oxygen permeability thereof is preferably 1 cc/(m²·day·atm) or lower.

As a result, the gas barrier properties of the functional film are further improved.

In FIG. 3, the substrate film 4 is a single-layer film, but the present invention is not limited thereto. The substrate film 4 may be a laminated film in which a plurality of layers are laminated. For example, as in a functional film 1c illustrated in FIG. 4, the substrate film 4 in which a barrier layer 5 is provided on one surface of a support film 9 may be used.

That is, a structure in which a barrier layer having impermeability to oxygen is laminated between the resin layer and the support film may be adopted.

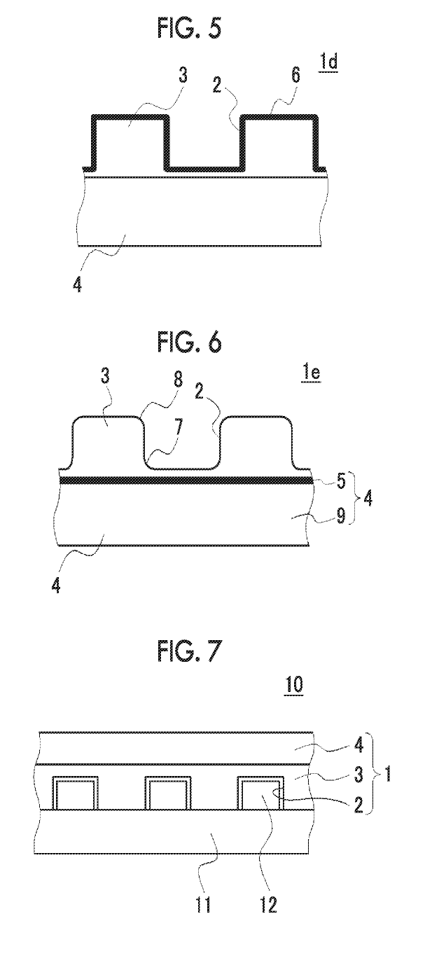

Further, as in a functional film 1d illustrated in FIG. 5, an uneven barrier layer 6 including at least an inorganic layer may be formed on a surface of the resin layer 3 on the recess portion 2 side.

In addition, the size or disposition pattern of the recess portions 2 is not particularly limited and may be appropriately designed depending on desired conditions. For the design, a geometric restriction for disposing the recess portions to be distant from each other in a plan view is considered. In addition, for example, in a case where a printing method is used as a method of forming the recess portions, there is also a restriction in that, unless the occupied area (in a plan view) of each of the recess portions is a given value or higher, printing cannot be performed. Further, it is necessary to set the shortest distance between recess portions adjacent to each other such that the oxygen permeability is 10 cc/(m²·day·atm) or lower. In consideration of the above-described restrictions, the desired shape, size, and disposition pattern may be designed.

In the embodiment, as illustrated in FIG. 1, the recess portions 2 have a quadrangular columnar shape and have a quadrangular shape in a plan view. However, the shape of the recess portions 2 is not particularly limited. The recess portions 2 may have a polygonal columnar shape or a circular columnar shape. In addition, in the above-described example, the bottom surface having a circular columnar shape or a polygonal columnar shape is disposed parallel to the substrate film surface. However, the bottom surface is not necessarily disposed parallel to the substrate film surface. In addition, the shape of each of the recess portions 2 may be unstructured.

In addition, in the embodiment, the recess portions 2 are disposed in a periodic pattern. However, as long as the recess portions 2 are discretely disposed, the recess portions 2 may be disposed in an aperiodic pattern within a range where the desired performance does not deteriorate.

In addition, the disposition and shape of the recess portions 2 may be set according to the disposition, size, and the like of an organic device to be used in combination.

Hereinafter, each of the components of the functional film according to the embodiment of the present invention will be described.

«Resin Layer Having Impermeability to Oxygen»

As a curable compound for forming the resin layer having impermeability to oxygen, a material with which a resin layer having high gas barrier properties can be formed, for example, a (meth)acrylate compound or an epoxy compound is more preferable.

Among the above-described curable compounds, a (meth)acrylate compound is preferable from the viewpoints of composition viscosity and photocuring properties, and an acrylate is more preferable. In addition, in the present invention, a polyfunctional polymerizable compound having two or more polymerizable functional groups is preferable. In the present invention, a mixing ratio between a monofunctional (meth)acrylate compound and a polyfunctional (meth)acrylate compound is preferably 80/20 to 0/100, more preferably 70/30 to 0/100, and still more preferably 40/60 to 0/100 by weight ratio. By selecting an appropriate ratio, sufficient curing properties can be obtained, and the viscosity of the composition can be reduced.

In the polyfunctional (meth)acrylate compound, a mass ratio between the bifunctional (meth)acrylate and the trifunctional or higher (meth)acrylate is preferably 100/0 to 20/80, more preferably 100/0 to 50/50, and still more preferably 100/0 to 70/30. The trifunctional or higher (meth)acrylate has higher viscosity than the bifunctional (meth)acrylate. Therefore, it is preferable that the amount of the bifunctional (meth)acrylate is large because the viscosity of the curable compound for forming the resin layer according to the present invention having impermeability to oxygen can be reduced.

It is preferable that a compound which has a substituent having an aromatic structure and/or an alicyclic hydrocarbon structure is included as the polymerizable compound from the viewpoint of improving impermeability to oxygen, it is more preferable that the content of the polymerizable compound having an aromatic structure and/or an alicyclic hydrocarbon structure is 50 mass % or higher with respect to the components, and it is still more preferable that the content of the polymerizable compound having an aromatic structure and/or an alicyclic hydrocarbon structure is 80 mass % or higher with respect to the components. As the polymerizable compound having an aromatic structure, a (meth)acrylate compound having an aromatic structure is preferable. As the (meth)acrylate compound having an aromatic structure, a monofunctional (meth)acrylate compound having a naphthalene structure, for example, a monofunctional acrylate such as 1- or 2-naphtyl (meth)acrylate, 1- or 2-naphtyl methyl (meth)acrylate, 1- or 2-naphtyl ethyl (meth)acrylate, or benzyl acrylate having a substituent on an aromatic ring, or a bifunctional acrylate such as catechol diacrylate or xylylene glycol diacrylate is more preferable. As the polymerizable compound having an alicyclic hydrocarbon structure, for example, isobornyl (meth)acrylate, dicyclopentanyl (meth)acrylate, dicyclopentanyloxyethyl (meth)acrylate, dicyclopentenyl (meth)acrylate, adamantyl (meth)acrylate, tricyclodecanyl (meth)acrylate, or tetracyclododecanyl (meth)acrylate is preferable.

In addition, in a case where (meth)acrylate is used as the polymerizable compound, acrylate is preferable to methacrylate from the viewpoint of excellent curing properties.

The oxygen permeability at the shortest distance between recess portions 2 adjacent to each other between which the resin layer 3 is interposed is preferably 10 cc/(m²·day·atm) or lower. The oxygen permeability at the shortest distance between recess portions 2 adjacent to each other in the resin layer 3 is more preferably 1 cc/(m²·day·atm) or lower and still more preferably 10⁻¹ cc/(m²·day·atm) or lower. The required shortest distance between the recess portions 2 varies depending on the composition of the resin layer 3.

As the SI unit of oxygen permeability, fm/(s·Pa) can be used. 1 fm/(s·Pa) can be converted into 8.752 cc/(m²·day·atm). fm is read as femtometer, and 1 fm=10⁻¹⁵ m.

The required shortest distance between the recess portions 2 varies depending on the composition of the resin layer 3. The shortest distance between recess portions 2 adjacent to each other in the resin layer 3 refers to the shortest distance in the film surface between recess portions 2 adjacent to each other in case of being observed from the functional film main surface. In addition, hereinafter, the shortest distance between recess portions 2 adjacent to each other will also be referred to as the width of the resin layer.

As described above, the required shortest distance between the recess portions 2 varies depending on the composition of the resin layer 3. For example, the shortest distance between adjacent recess portions 2 adjacent to each other, that is, the width of the resin layer is preferably 5 μm to 300 μm, more preferably 10 μm to 200 μm, and still more preferably 15 μm to 100 μm. In a case where the width of the resin layer is very short, it is difficult to secure required oxygen permeability. In a case where the width of the resin layer is very long, the proportion of the functional material per unit area is reduced, and a sufficient function cannot be exhibited.

The modulus of elasticity of the resin layer 3 is preferably 0.5 GPa to 10 GPa, more preferably 1 GPa to 7 GPa, and still more preferably 3 GPa to 6 GPa. By adjusting the modulus of elasticity of the resin layer to be in the above-described range, while maintaining the oxygen permeability, deletion during the formation of the resin layer can be prevented, which is preferable.

The modulus of elasticity of the resin layer is measured using a method described in JIS K 7161 or the like.

As a material for forming the resin layer 3, a compound having a bifunctional or higher photopolymerizable crosslinking group is preferable, and examples thereof include an alicyclic (meth)acrylate such as urethane (meth)acrylate or tricyclodecane dimethanol di(meth)acrylate, a (meth)acrylate having a hydroxyl group such as pentaerythritol triacrylate, an aromatic (meth)acrylate such as modified bisphenol A di(meth)acrylate, dipentaerythritol di(meth)acrylate, 3,4-epoxy-cyclohexyl methyl (meth)acrylate, 3′,4′-epoxycyclohexylmethyl 3,4-epoxycyclohexanecarboxylate, and bisphenol A epoxy. In particular, from the viewpoint of improving impermeability to oxygen, it is preferable that at least urethane (meth)acrylate or an epoxy compound is included. By using a compound having a urethane bond or a polar functional group such as a hydroxyl group or a carboxyl group, an intermolecular interaction can be improved, and the resin layer having high impermeability to oxygen can be obtained.

(Additives)

Optionally, the material for forming the resin layer may include a photopolymerization initiator, an inorganic layer compound, light scattering particles, an antioxidant, a peeling accelerator, or a solvent.

(Photopolymerization Initiator)

It is preferable that the curable compound for forming the resin layer 3 includes a photopolymerization initiator. As the photopolymerization initiator, any compound that generates an active species for polymerization of the above-described polymerizable compounds by light irradiation can be used. Examples of the photopolymerization initiator include a cationic polymerization initiator and a radical polymerization initiator. The photopolymerization initiator is appropriately selected according to the material for forming the resin layer.

(Inorganic Layer Compound)

The curable compound for forming the resin layer 3 may include a compound such as an inorganic layer compound of imparting a so-called maze effect of extending the diffusion lengths of gaseous molecules in the resin layer to improve gas barrier properties. Examples of the inorganic layer compound include talc, mica, feldspar, kaolinite (kaolin clay), pyrophyllite (pyrophyllite clay), sericite, bentonite, smectite and vermiculite (for example, montmorillonite, beidellite, nontronite, or saponite), organic bentonite, organic smectite, and a flat inorganic oxide such as a flat alumina. In addition, the inorganic layer compound may be surface-treated in order to improve dispersibility in the material for forming the resin. Further from the viewpoint of obtaining the excellent maze effect, the aspect ratio of the inorganic layer compound is preferably 10 to 1000. In a case where the aspect ratio is 10 or lower, the effect of improving gas barrier properties due to the maze effect is low. In a case where the aspect ratio is 1000 or higher, the inorganic layer is brittle and thus may crush during a manufacturing process.

Among these, one kind can be used alone, or two or more kinds can be used in combination. Examples of a commercially available product of the inorganic layer compound include ST-501 and ST-509 manufactured by Shiraishi Calcium Co., Ltd., SOMASIF series and MICRO MICA series manufactured by Katakura & Co-op Agri Corporation, and SERAPH series manufactured by Kinsei Matec Co., Ltd. Among these, SERAPH series having high transparency can be preferably used in the functional film according to the embodiment of the present invention.

«Substrate Film»

It is preferable that the substrate film 4 is a film having a function of suppressing permeation of oxygen. In the embodiment illustrated in FIG. 4, the barrier layer 5 is provided on one surface of the support film 9. In the aspect, due to the presence of the support film 9, the strength of the functional film can be improved, and film formation can be easily performed. In the embodiment illustrated in FIG. 4, the barrier layer 5 is provided on one surface of the support film 9. However, as illustrated in FIG. 3, the substrate film may be configured by only the support having sufficient barrier properties.

It is preferable that the substrate film 4 is a belt-shaped support having flexibility that is transparent to visible light. Here, “transparent to visible light” represents that the light transmittance in a visible range is 80% or higher and preferably 85% or higher. The light transmittance used as an index for transparency can be measured using a method described in JIS-K 7105. That is, using an integrating sphere light transmittance measuring device, the total light transmittance and the scattered light amount are measured, and the diffuse transmittance is subtracted from the total light transmittance to obtain the light transmittance. The details of the support having flexibility can be found in paragraphs “0046” to “0052” of JP2007-290369A and paragraphs “0040” to “0055” of JP2005-096108A.

In addition, the total light transmittance of the barrier layer 5 formed in the substrate film 4 in a visible range is preferably 80% or higher and more preferably 85% or higher. The visible range refers to a wavelength range of 380 nm to 780 nm, and the total light transmittance refers to an average light transmittance value in a visible range.

The oxygen permeability of the substrate film 4 is preferably 1.00 cc/(m²·day·atm) or lower. The oxygen permeability is more preferably 0.1 cc/(m²·day·atm) or lower, still more preferably 0.01 cc/(m²·day·atm) or lower, and still more preferably 0.001 cc/(m²·day·atm) or lower. Here, the oxygen permeability is a value measured using an oxygen permeability measuring device (OX-TRAN 2/20: trade name, manufactured by Mocon Inc.) under conditions of measurement temperature: 23° C. and relative humidity: 90%.

It is preferable that the substrate film 4 has not only a gas barrier function of blocking oxygen but also a function of blocking moisture (water vapor). The moisture permeability (water vapor permeability) of the substrate film 4 is preferably 0.10 g/(m²·day·atm) or lower and more preferably 0.01 g/(m²·day·atm) or lower.

From the viewpoints of impact resistance and the like of the functional film, the average thickness of the substrate film 4 is preferably 10 μm to 500 μm, more preferably 20 μm to 400 μm, and still more preferably 30 μm to 300 μm. From the viewpoint of reducing the thickness of the device, the average thickness of the substrate film 4 is preferably 40 μm or less and more preferably 25 μm or less.

In addition, the in-plane retardation Re(589) of the substrate film 4 at a wavelength of 589 nm is preferably 1000 nm or lower, more preferably 500 nm or lower, and still more preferably 200 nm or lower.

In a case where whether or not foreign matter or defects are present is inspected after the preparation of the functional film, foreign matter or defects can be easily found by disposing two polarizing plates at extinction positions and inserting the functional film between the two polarizing plates to observe the functional film. In a case where Re(589) of the support is in the above-described range, foreign matter or defects can be easily found during the inspection using the polarizing plates, which is preferable.

Here, Re(589) can be measured at the wavelength λ using AxoScan OPMF-1 (manufactured by Opto Science Inc.) by causing light at an input wavelength of 589 nm to be incident in a film normal direction.

(Support Film)

It is preferable that the support film 9 has barrier properties to oxygen and moisture. (referable examples of the support film include a polyethylene terephthalate film, a film which includes a polymer having a cyclic olefin structure, and a polystyrene film.

(Barrier Layer)

In the substrate film 4, the barrier layer 5 that is formed adjacent to the resin layer 3 and the uneven barrier layer 6 that is formed on the recess portions 2 include at least one inorganic layer.

The barrier layer 5 and the uneven barrier layer 6 have the same structure except for the position and the shape to be formed. In the following description, in a case where it is not necessary to distinguish the barrier layer 5 and the uneven barrier layer 6 from each other, both the barrier layer 5 and the uneven barrier layer 6 will be referred to as “barrier layer”.

The barrier layer may include at least one inorganic layer and at least one organic layer. From the viewpoint of improving light fastness, it is preferable that multiple layers are laminated as described above because barrier properties can be further improved. On the other hand, as the number of layers laminated increases, the light transmittance of the substrate film is likely to decrease. Therefore, it is preferable to increase the number of layers laminated in a range where a high light transmittance can be maintained.

The total light transmittance of the barrier layer in a visible range is preferably 80% or higher, and the oxygen permeability thereof is preferably 1.00 cc/(m²·day·atm) or lower.

The oxygen permeability of the barrier layer is more preferably 0.1 cc/(m²·day·atm) or lower, still more preferably 0.01 cc/(m²·day·atm) or lower, and still more preferably 0.001 cc/(m²·day·atm) or lower.

The lower the oxygen permeability, the better. In addition, the higher the total light transmittance in a visible range, the better.

Inorganic Layer

The inorganic layer is a layer including an inorganic material as a major component in which the content of the inorganic material is preferably 50 mass % or higher, more preferably 80 mass % or higher, and still more preferably 90 mass % or higher. Still more preferably, the inorganic layer is a layer consisting of only an inorganic material.

It is preferable that the inorganic layer is a layer having a gas barrier function of blocking oxygen. Specifically, the oxygen permeability of the inorganic layer is preferably 1.00 cc/(m²·day·atm) or lower. The oxygen permeability of the inorganic layer can be obtained by bonding a wavelength conversion layer to a detection portion of an oxygen analyzer (manufactured by Orbisphere Laboratories) through silicone grease and converting an equilibrium oxygen concentration value into an oxygen permeability. It is preferable that the inorganic layer also has a function of blocking water vapor.

The barrier layer may include two or three inorganic layers.

The thickness of the inorganic layer may be 1 nm to 500 nm and is preferably 5 nm to 300 nm and more preferably 10 nm to 150 nm. By adjusting the thickness of the inorganic layer to be in the above-described range, reflection from the inorganic layer can be suppressed while realizing excellent barrier properties, and the functional film having a higher light transmittance can be provided.

The inorganic material constituting the inorganic layer is not particularly limited, and various inorganic compounds such as a metal, an inorganic oxide, an inorganic nitride, or an inorganic oxynitride can be used. As an element constituting the inorganic material, silicon, aluminum, magnesium, titanium, tin, indium, or cerium is preferable. The inorganic material may include one element or two or more elements among the above elements. Specific examples of the inorganic compound include silicon oxide, silicon oxynitride, aluminum oxide, magnesium oxide, titanium oxide, tin oxide, an indium oxide alloy, silicon nitride, aluminum nitride, and titanium nitride. In addition, as the inorganic layer, a metal film such as an aluminum film, a silver film, a tin film, a chromium film, a nickel film, or a titanium film may be provided.

In particular, it is more preferable that the inorganic layer having barrier properties includes at least one compound selected from silicon nitride, silicon oxynitride, silicon oxide, and aluminum oxide among the above materials. The inorganic layer formed of the above materials has excellent adhesiveness with the organic layer. Therefore, in a case where a pin hole is formed on the inorganic layer, the organic layer can be effectively embedded in the pin hole, and fracturing can be suppressed. Further, in a case where the inorganic layers are laminated, an extremely good inorganic layer film can be formed, and barrier properties can be further improved. In addition, it is more preferable that the inorganic barrier layer is formed of a silicon nitride from the viewpoint of suppressing light absorption in the barrier layer.

A method of forming the inorganic layer is not particularly limited. For example, various film forming methods in which a film forming material can be evaporated or scattered to be deposited on a deposition target surface can be used.

Examples of the method of forming the inorganic layer include: a vacuum deposition method of heating and depositing an inorganic material such as an inorganic oxide, an inorganic nitride, an inorganic oxynitride, or a metal; an oxidation deposition method of introducing oxygen gas and oxidizing an inorganic material as a raw material for deposition; a sputtering method of introducing argon gas and oxygen gas and sputtering an inorganic material as a target material for deposition; a physical vapor deposition (PVD) method, such as an ion plating method, of heating an inorganic material with a plasma beam generated by a plasma gun for deposition; and in a case where a deposited film formed of silicon oxide is formed, and a plasma chemical vapor deposition (CVD) method of using an organic silicon compound as a raw material.

Alternatively, as the method of forming the inorganic layer, for example, a coating method, a printing method, or a transfer method can also be applied.

Organic Layer

“Organic layer” is a layer including an organic material as a major component in which the content of the organic material is preferably 50 mass % or higher, more preferably 80 mass % or higher, and still more preferably 90 mass % or higher.

The details of the organic layer can be found in paragraphs “0020” to “0042” of JP2007-290369A and paragraphs “0074” to “0105” of JP2005-096108A. It is preferable that the organic layer includes a cardo polymer within a range where the adhesive strength conditions are satisfied. As a result, adhesiveness between the organic layer and an adjacent layer, in particular, adhesiveness between the organic layer and the inorganic layer is improved, and more favorable gas barrier properties can be realized. The details of the cardo polymer can be found in paragraphs “0085” to “0095” of JP2005-096108A.

The thickness of the organic layer is preferably in a range of 0.05 to 10 μm and more preferably in a range of 0.5 to 10 μm. In a case where the organic layer is formed using a wet coating method, the thickness of the organic layer is preferably in a range of 0.5 to 10 μm and more preferably in a range of 1 to 5 μm. In a case where the organic layer is formed using a dry coating method, the thickness of the organic layer is preferably in a range of 0.05 to 5 μm and more preferably in a range of 0.05 to 1 μm. By adjusting the thickness of the organic layer which is formed using a wet coating method or a dry coating method, adhesiveness with the inorganic layer can be further improved.

Other details of the inorganic layer and the organic layer can be found in JP2007-290369A, JP2005-096108A, and US201210113672A1.

In the functional film, the organic layer may be formed as an underlayer of the inorganic layer or as a protective layer of the inorganic layer. In addition, in a case where two or more inorganic layers are provided, the organic layer may be laminated between the inorganic layers.

<Method of Forming Functional Film>

Next, an example of steps of forming the functional film according to the embodiment of the present invention will be described.

(Coating Solution Preparing Step)

In a coating solution preparing step, a coating solution for forming the resin layer is prepared. Specifically, respective components such as a curable compound dispersed in an organic solvent or a polymerization initiator are mixed with each other in a tank or the like to prepare a coating solution. The coating solution does not necessarily include the organic solvent.

(Resin Layer Forming Step)

The coating solution for forming the resin layer is applied to the substrate film 4, a mold having an uneven pattern is pressed into contact with the applied coating solution for forming the resin layer to form a predetermined pattern including a plurality of recess portions, and the coating solution for forming the resin layer is cured. As a result, the functional film 1 in which the resin layer 3 including the recess portions is laminated on the substrate film 4 is prepared.

In the curing process of the resin layer forming step, thermally curing, photocuring using ultraviolet light, or the like may be appropriately selected according to the coating solution.

In a case where the resin layer 3 is cured by photocuring using ultraviolet light, the irradiation dose of the ultraviolet light is preferably 100 to 10000 mJ/cm².

In a case where the resin layer 3 is cured by thermally curing, it is preferable that the resin layer 3 is heated to 20° C. to 100° C.

In the method of forming the functional film, the respective steps may be continuously performed with a so-called roll-to-roll (RtoR) method, or the respective steps may be performed with a sheet type using a cut sheet-shaped substrate film.

Here, a method of forming the recess portions (uneven pattern) on the coating solution for forming the resin layer applied to the substrate film 4 will be specifically described.

In order to form the pattern, as described above, the method of forming the fine uneven pattern by pressing the mold having the uneven pattern into contact with the coating solution for forming the resin layer applied to the substrate film can be used.

In addition, the pattern can also be formed using an ink jet method or a dispenser method.

Here, as the mold, a mold having a pattern to be transferred is used. The pattern on the mold can be formed, for example, by photolithography, electron beam lithography, or the like depending on a desired processing accuracy. However, a mold pattern forming method is not particularly limited.

A light-transmitting mold material is not particularly limited as long as it has a predetermined strength and durability. Specific examples of the light-transmitting mold material include glass, quartz, an optically transparent resin such as PMMA or a polycarbonate resin, a transparent metal deposited film, a flexible film such as polydimethylsiloxane, a photocured film, and a metal film such as SUS.

On the other hand, a light non-transmitting mold material is not particularly limited as long as it has a predetermined strength. Specific examples of the non-transmitting mold material include a ceramic material, a deposited film, a magnetic film, a reflection film, a metal substrate such as Ni, Cu, Cr, or Fe, and a substrate formed of SiC, silicon, silicon nitride, polysilicon, silicon oxide, amorphous silicon, or the like. In addition, the shape of the mold is not particularly limited may be either a plate shape or a roll shape. The roll-shaped mold is applied particularly in a case where continuous productivity of transfer is required.

A mold having undergone a mold release treatment in order to improve releasability between the curable compound and the mold surface may be used. Examples of this mold include a mold coated with a material having excellent water and oil repellency. Specifically, polytetrafluoroethylene (PTFE) or diamond-like carbon (DLC) having undergone physical vapor deposition (PVD) or chemical vapor deposition (CVD) or a mold treated with a silane coupling agent such as silicon silane coupling agent or a fluorine silane coupling agent can be used. For example, a commercially available release agent such as OPTOOL DSX (manufactured by Daikin Industries, Ltd.) and Novec EGC-1720 (manufactured by Sumitomo 3M Ltd.) can be preferably used.

Specific examples of the method of forming the uneven pattern using the mold include: a thermal imprint method of forming the fine uneven pattern by pressing the mold into contact with the resin layer applied to and cured on the substrate film in a state where the resin layer or the mold is heated; a photoimprint method of forming the fine uneven pattern by pressing the mold having the uneven pattern into contact with the coating solution for forming the resin layer applied to the substrate film and then curing the resin layer with light; and a melt molding method of forming the fine uneven pattern. In particular, from the viewpoints of increasing the production rate and reducing the investment in facilities, a photoimprint method is preferable.

In a case where the photoimprint lithography is performed, typically, the mold pressure is preferably 10 atm or lower. By adjusting the mold pressure to be 10 atm or lower, the mold or the substrate is not likely to be deformed, and the pattern accuracy tends to be improved. In addition, since the pressure is low, the size of the device tends to be capable of being reduced, which is preferable. It is preferable that the mold pressure is selected in a range where the uniformity of mold transfer can be secured and the remaining of the curable compound on a mold protrusion can be reduced.

The irradiation dose of light irradiation in a curing portion is not particularly limited as long as it is sufficiently higher than an irradiation dose required for curing. The irradiation dose required for curing is appropriately determined by investigating the consumption of an unsaturated bond in the curable composition or the tackiness of the cured film.

In addition, in the photoimprint lithography, the substrate temperature during light irradiation is typically room temperature. However, in order to improve reactivity, light irradiation may be performed while heating the substrate. As a step prior to light irradiation, vacuum conditioning is effective for preventing incorporation of bubbles, suppressing a decrease in reactivity caused by incorporation of oxygen, and improving adhesiveness between the mold and the curable composition. Therefore, light irradiation may be performed in a vacuum state. In addition, in the pattern forming method, the vacuum degree during light irradiation is preferably in a range of 10⁻¹ Pa to 1 atm.

Light used for curing the curable compound is not particularly limited, and examples thereof include high-energy ionizing radiation, light at a wavelength in a near-ultraviolet range, a far-ultraviolet range, a visible range, an infrared range, or the like, and radiation. As a high-energy ionizing radiation source, an electron beam accelerated by an accelerator such as a Cockcroft accelerator, a Van De Graaff accelerator, linear accelerator, a betatron, or a cyclotron is used industrially most conveniently and economically. In addition, radiations such as γ-rays, X-rays, α-rays, neutron rays, or proton beams radiating from a radioisotope, a nuclear reactor, or the like can also be used. Examples of an ultraviolet light source include an ultraviolet fluorescent lamp, a low-pressure mercury lamp, a high-pressure mercury lamp, an ultrahigh pressure mercury lamp, a xenon lamp, a carbon arc lamp, a sun lamp, and a light emitting diode (LED). Examples of the radiation include microwaves and extreme ultraviolet (EUV) rays. In addition, LED light, semiconductor laser light, or laser light used for semiconductor microfabrication such as 248 nm KrF excimer laser light or 193 nm ArF excimer laser can also be preferably used in the present invention. These light components may be monochromatic light or light (mixed light) having a plurality of different wavelengths.

During exposure, the exposure illuminance is preferably in a range of 1 mW/cm² to 1000 mW/cm². It is preferable that the exposure illuminance is 1 mW/cm² or higher because the exposure time can be reduced and the productivity can be improved. It is preferable that the exposure illuminance is 1000 mW/cm² or lower because deterioration in the properties of a permanent film caused by a side reaction can be suppressed. The exposure dose is preferably in a range of 5 mJ/cm² to 10000 mJ/cm². In a case where the exposure dose is lower than 5 mJ/cm², the exposure margin is narrowed, photocuring becomes insufficient, and thus a problem of adhesion of unreacted materials to the mold is likely to occur. In a case where the exposure dose is higher than 10000 mJ/cm², deterioration of a permanent film caused by decomposition of the composition may occur. Further, in order to prevent inhibition of radical polymerization caused by oxygen during exposure, inert gas such as nitrogen or argon may be caused to flow such that the oxygen concentration is controlled to be lower than 100 mg/L.

After curing the curable compound by light irradiation in the curing portion, a step of further applying heat to the curable compound to cure the curable compound may be further provided. The heating temperature at which the curable compound is heated and cured after light irradiation is preferably 80° C. to 280° C. and more preferably 100° C. to 200° C. In addition, the period of time for which heat is applied is preferably 5 to 60 minutes and more preferably 15 minutes to 45 minutes.

The uneven pattern formed on the resin layer can be in any form, for example, a lattice mesh pattern in which openings of the recess portions have a square shape or a rectangular shape, a honeycomb pattern in which openings of the recess portions have a regular hexagonal shape, a sea-island pattern in which openings of the recess portions have a circular shape, a complex pattern in which openings of the recess portions have a combination of a regular pentagonal shape and a regular hexagonal shape or a combination of circular shapes having different diameters, or a pattern in which there is an in-plane distribution in the size of a hexagonal shape.

Among these, in a case where the resin layer is formed using a photoimprint method, a regular polygonal shape such as a square shape or a regular hexagonal shape or a circular pattern is preferable from the viewpoint of suppressing deletion of a partition wall in a case where the resin layer is released from the mold.

In addition, in the example, the step of curing the resin layer is performed in a state where the mold is adhered. However, the step of curing the resin layer may be performed after releasing the mold. It is preferable that the step of curing the resin layer is performed in a state where the mold is adhered.

In a case where the thermal imprint method is performed, the mold pressure is preferably in a range of 0.1 to 100 MPa. In addition, it is preferable that the temperature of the mold and the resin layer is in a predetermined range. In general, the mold temperature is set to be higher than or equal to a glass transition temperature (Tg) of the resin layer and the substrate temperature is set to be lower than the mold temperature in many cases.

In a case where the melt molding method is performed, a resin to be molded is heated to a temperature of a melting point or higher, the molten resin (melt) is caused to flow between the mold and the substrate film, and then the molten resin and the mold are pressed into contact with each other and cooled. In a case where the melt molding method is performed, as a material for forming the resin layer 3, a polymer having a low oxygen permeability is preferable, and specific examples thereof include polyvinyl alcohol (PVA) and a polyester resin such as a polyethylene-vinyl alcohol copolymer (EVOH), polyvinylidene chloride (PVDC), polyvinylidene fluoride (PVDF), or polyethylene terephthalate (PET). Among these, from the viewpoints of transparency, heat resistance, and light fastness, (modified) polyvinyl alcohol is preferable, and a polyethylene-vinyl alcohol copolymer (EVOH) is more preferable.

In order to secure adhesiveness with the substrate film on which the resin layer is to be formed, an anchor coat layer may be provided on the substrate film. A material of the anchor coat layer is appropriately selected according to the materials of the resin layer and the substrate film and the like. For example, in a case where the resin layer is formed of EVOH and the substrate film is formed of PET, as tile material of the anchor coat layer, for example, a urethane, a polyethyleneimine, a polybutadiene, or a (modified) polyolefin compound can be used. From the viewpoint of excellent water resistance and adhesive strength, an anchor coat material such as a urethane or a (modified) polyolefin compound is most preferable. Specific examples of a commercially available product include EL-530 A/B manufactured by Toyo-Morton Ltd. and TAKELAC A/TAKENATE A series, ADMER series, and UNISTOLE series manufactured by Mitsui Chemicals Inc.

<Organic EL Element>

An organic EL element according to the embodiment of the present invention has a configuration in which an organic EL device is sealed with the above-described functional film.

FIG. 7 is a schematic cross-sectional view illustrating an example of the organic EL element according to the embodiment of the present invention.

The organic EL element 10 illustrated in FIG. 7 includes: an organic EL substrate 11; and a plurality of organic EL devices 12 and the functional film 1 according to the embodiment of the present invention that are formed on the organic EL substrate 11.

As illustrated in the FIG. 7, the functional film 1 is laminated such that the surface where the recess portions 2 are formed faces the organic EL device 12 side. In addition, the functional film 1 is laminated to align the positions of the recess portions 2 and the positions of the organic EL devices 12 with each other such that the organic EL devices 12 are disposed in the recess portions 2.

The functional film 1 is bonded to the organic EL substrate 11 and the organic EL devices 12 through a well-known adhesive of the related art used in an organic EL device.

In addition, a configuration may be adopted in which the organic EL devices 12 are formed in the recess portions 2 of the functional film 1 and the organic EL substrate 11 is bonded to the functional film 1 in which the organic EL devices 12 are formed.

The organic EL device 12 is not particularly limited, and a well-known organic EL device of the related art can be used. For example, the organic EL device 12 includes: an organic electroluminescence light emitting layer; and a transparent electrode and a reflecting electrode as a pair of electrodes between which the organic electroluminescence light emitting layer is interposed.

In addition, as the organic EL substrate 11, various well-known organic EL substrates of the related art such as a glass substrate can be used.

### EXAMPLES

Hereinafter, the present invention will be described in detail using examples. Materials, used amounts, ratios, treatment details, treatment procedures, and the like shown in the following examples can be appropriately changed within a range not departing from the scope of the present invention. Accordingly, the scope of the present invention is not limited to the following specific examples.

### Example 1

### Preparation of Functional Film

(Preparation of Substrate Film)

A barrier film was prepared as follows in which the barrier layer 5 including an inorganic layer and an organic layer to which the following composition was applied was formed on the support film 9 formed of polyethylene terephthalate (PET) as the substrate film 4, the organic layer being an underlayer and a protective layer of the inorganic layer.

As the support film 9, a polyethylene terephthalate (PET) film (trade name: COSMOSHINE (registered trade name) A4300, manufactured by Toyoho Co., Ltd.) having a thickness of 23 μm was used, and the organic layer and the inorganic layer were formed in this order on a single surface of the support film 9 in the following procedure.

Formation of Organic Layer

Trimethylolpropane triacrylate (TMPTA (trade name), manufactured by Daicel-Allnex Ltd.) and a photopolymerization initiator (ESACURE (registered trade name) KTO 46 (trade name), manufactured by Lamberti S.p.A.) were prepared and were weighed such that a mass ratio thereof was 95:5. These components were dissolved in methyl ethyl ketone. As a result, a coating solution having a concentration of solid contents of 15% was obtained. This coating solution was applied to the above-described PET film using a roll-to-roll method with a die coater and was allowed to pass through a drying zone at 50° C. for 3 minutes. Next, in a nitrogen atmosphere, the coating solution was irradiated with ultraviolet light (cumulative irradiation dose: about 600 mJ/cm²) to be cured, and the PET film was wound. The thickness of the organic layer formed on the support was 1 μm.

Formation of Inorganic Layer

Next, the inorganic layer (silicon nitride layer) was formed on the surface of the organic layer using a roll-to-roll chemical vapor deposition (CVD) device. As raw material gases, silane gas (flow rate: 160 sccm), ammonia gas (flow rate: 370 sccm), hydrogen gas (flow rate: 590 sccm), and nitrogen gas (flow rate: 240 sccm) were used. As a power supply, a high-frequency power supply having a frequency of 13.56 MHz was used. The film forming pressure was 40 Pa, and the achieved thickness was 50 nm. This way, the inorganic layer was formed on the surface of the organic layer formed on the support.

Formation of Second Organic Layer

Further, a second organic layer was laminated on a surface of the inorganic layer. In order to form the second organic layer, 5.0 parts by mass of a photopolymerization initiator (trade name “IRGACURE 184”, manufactured by BASF SE) was weighed with respect to 95.0 parts by mass of a urethane acrylate polymer (trade name “ACRYD 8BR 930”, manufactured by Taisei Fine Chemical Co., Ltd.), and these components were dissolved in methyl ethyl ketone. As a result, a coating solution having a concentration of solid contents of 15% was obtained.

This coating solution was directly applied to a surface of the above-described inorganic layer using a roll-to-roll method with a die coater and was allowed to pass through a drying zone at 100° C. for 3 minutes. Next, while holding the laminate with a heat roll heated to 60° C., the coating solution was irradiated with ultraviolet light (cumulative irradiation dose: about 600 mJ/cm²) to be cured, and the laminate was wound. The thickness of the second organic layer formed on the support was 1 μm. This way, the barrier film (substrate film) on which the barrier layer including the organic layer, the inorganic layer, and the second organic layer was formed was prepared.

The oxygen permeability of the barrier film which was measured using OX-TRAN 2/20 (manufactured by Mocon Inc.) was 4.0×10⁻³ cc/(m²·day·atm) or lower.

(Formation of Resin Layer)

As a coating solution 1 for forming the resin layer, the respective components such as the curable compound, the polymerization initiator, and the silane coupling agent were mixed with each other in a tank or the like to prepare a coating solution.

Composition of Coating Solution 1 for Forming Resin Layer

A coating solution for forming the resin layer having the following composition was prepared as the coating solution 1.

Urethane (meth)acrylate (U-4HA (manufactured by Shin-Nakamura Chemical Co., Ltd.)): 49.5 parts by mass

Tricyclodecane dimethanol diacrylate (A-DCP (manufactured by Shin-Nakamura Chemical Co., Ltd.): 49.5 parts by mass

Photopolymerization initiator (IRGACURE 819 (manufactured by BASF SE)): 1 part by mass

Formation of Resin Layer

The coating solution for forming the resin layer was applied to the substrate film 4 to transfer the recess portions and was photocured. As a result, the resin layer 3 including a plurality of recess portions was formed. A curvature was not imparted to a corner portion of a mold used for transfer, and a mold having a right-angled corner portion was used.

Here, the recess portions had a lattice pattern having a square shape of 250 μm×250 μm, the depth h of the recess portions was set as 40 μm, and the width t thereof was set as 50 μm. That is, the aspect ratio h/t was 0.8. A curvature was not imparted to a corner portion of the recess portions, and the corner portion had a right angle.

In addition, during photocuring, the resin layer was cured by irradiating the resin layer with ultraviolet light at 500 mJ/cm² from the first substrate film side using an air-cooled metal halide lamp (manufactured by Eye Graphics Co., Ltd.) of 200 W/cm.

In addition, the modulus of elasticity of the cured resin layer was measured according to the standards of JIS K 7161 and was 3.1 GPa.

In addition, the oxygen permeability of the cured resin layer was measured and was 1×10⁻¹ cc/(m²·day·atm).

### Example 2

A functional film was prepared under the same conditions as those of Example 1, except that recess portions having a round corner portion with a curvature radius of 50 μm were used and the curvature radius of the recess portions was set as 50 μm.

### Example 3

A functional film was prepared under the same conditions as those of Example 1, except that the uneven barrier layer 6 including the inorganic layer was formed on the surface of the resin layer 3 on the recess portion 2 side and the barrier layer was not formed on the substrate film 4.

Formation of Inorganic Barrier Layer

AQUAMICA NP140 (manufactured by AZ Electronic Materials Co., Ltd.) was applied to the surface of the resin layer 3 on the recess portion 2 side using a die coater to form a coating film having a thickness of 50 μm. Next, this coating film was allowed to pass through a heating zone at 100° C. for 3 minutes to be dried and cured. As a result, an inorganic barrier layer having a thickness of 1 μm was formed.

### Example 4

A functional film was prepared under the same conditions as those of Example 1, except that the substrate film was not provided and the thickness of the resin layer 3 was set as 5000 μm. That is, the functional film according to Example 4 was a single-layer film including the resin layer 3 including the recess portions 2.

The resin layer 3 was formed by applying the coating solution 1 to a temporary support (A4100, manufactured by Toyobo Co., Ltd., 100 μm) to transfer the recess portions, curing the coating solution 1, and then releasing the coating film from the temporary support.

The oxygen permeability of the cured resin layer was measured and was 1×10⁻¹ cc/(m²·day·atm).

### Comparative Example 1

A functional film was prepared under the same conditions as those of Example 1, except that the resin layer was not provided. That is, the barrier film used in Example 1 was prepared.

### Comparative Example 2

A functional film was prepared under the same conditions as those of Example 1, except that the following coating solution 2 for forming the resin layer was used instead of the coating solution 1.

The modulus of elasticity of the cured resin layer was measured according to the standards of JIS K 7161 and was 0.0015 GPa.

In addition, the oxygen permeability of the cured resin layer was measured and was 1.3×10³ cc/(m²·day·atm).

Composition of Coating Solution 2 for Forming Resin Layer

A coating solution for forming the resin layer having the following composition was prepared as the coating solution 1.

Ultraviolet curable liquid silicone rubber (PDMS (manufactured by Shin-Etsu Chemical Co., Ltd.))

### Comparative Example 3

A functional film was prepared under the same conditions as those of Example 1, except that the following coating solution 3 for forming the resin layer was used instead of the coating solution 1.

The modulus of elasticity of the cured resin layer was measured according to the standards of JIS K 7161 and was 110 GPa.

In addition, the oxygen permeability of the cured resin layer was measured and was 5×10⁻² cc/(m²·day·atm).

Composition of Coating Solution 3 for Forming Resin Layer

A coating solution for forming the resin layer having the following composition was prepared as the coating solution 1.

Urethane (meth)acrylate (U-4HA (manufactured by Shin-Nakamura Chemical Co., Ltd.)): 74.5 parts by mass

Synthetic plate-like alumina (SERAPH, manufactured by Kinsei Matec Co., Ltd.): 24.5 parts by mass

Photopolymerization initiator (IRGACURE 819 (manufactured by BASF SE)): 1 part by mass

<Evaluation>

The functional film was disposed on the organic EL devices disposed on the glass substrate (organic EL substrate) to evaluate deterioration in luminance.

The organic EL devices had a length of 100 μm, a width of 100 μm, and a height of 40 μm and were provided on the glass substrate in a lattice shape in the number of 4×4 at an interval of 200 μm.

The glass substrate and the organic EL device were bonded to the functional film using a thermally curable adhesive (EPO-TECK 310, manufactured by Daizo Corporation) and were heated at 65° C. for 3 hours to cure the adhesive. As a result, the sealed organic EL element was prepared.

The deterioration in the luminance of the organic EL element was evaluated as follows.

First, immediately after the preparation, a voltage of 7 V was applied to the organic EL element using a SMU 2400 source measure unit (manufactured by Keithley) to emit light, and the initial luminance thereof was measured using a luminance colorimeter (trade name: “SR3”, manufactured by Topcon Corporation) provided at a position at a distance of 520 mm in a direction perpendicular to the light emitting surface of the organic EL element.

Next, the organic EL element was left to stand in a dark room at 60° C. and a relative humidity of 90% for 500 hours, and the luminance was measured as described above.

A case where the luminance measured after 500 hours was 95% or higher with respect to the initial luminance was evaluated as A, a case where the luminance measured after 500 hours was lower than 95% and 90% or higher with respect to the initial luminance was evaluated as B, and a case where the luminance measured after 500 hours was lower than 90% with respect to the initial luminance was evaluated as C.

The evaluation results of Examples and Comparative Examples are shown in Table 1.

TABLE 1

| | Substrate | | Corner | Modulus of | Oxygen Permeability | Deterioration |
|---|---|---|---|---|---|---|
| | Film | Resin Layer | Portion | Elasticity GPa | cc/(m² · day · atm) | in Luminance |
| Example 1 | Barrier | Resin Layer | Not | 3.1 | 1 × 10⁻¹ | B |
| | Film | Including Recess | Rounded | | | |
| | | Portions | | | | |
| Example 2 | Barrier | Resin Layer | Rounded | 3.1 | 1 × 10⁻¹ | A |
| | Film | Including Recess | | | | |
| | | Portions | | | | |
| Example 3 | PET | Resin Layer | Rounded | 3.1 | 5 × 10⁻² | A |
| | Film | Including Recess | | | | |
| | | Portions + Uneven | | | | |
| | | Barrier Film | | | | |
| Example 4 | None | Resin Layer | Not R | 3.1 | 1 × 10⁻¹ | B |
| | | Including Recess | Rounded | | | |
| | | Portions | | | | |
| Comparative | Barrier | None | — | — | 4 × 10⁻³ | C |
| Example 1 | Film | | | | | |
| Comparative | Barrier | Resin Layer | Not R | 0.0015 | 1.3 × 10⁺³ | C |
| Example 2 | Film | Including Recess | Rounded | | | |
| | | Portions | | | | |
| Comparative | Barrier | Resin Layer | Not R | 110 | 5 × 10⁻² | C |
| Example 3 | Film | Including Recess | Rounded | | | |
| | | Portions | | | | |

It can be clearly seen from the results of Table 1 that, in the organic EL element sealed with the functional film according to the present invention, the deterioration in luminance over time is small and the moisture-heat resistance is excellent. That is, it can be seen that the functional film can exhibit high gas barrier properties.

In addition, it can be seen from a comparison between Examples 1 and 2 that it is preferable that the partition wall has an R shape because the deterioration in luminance is small.

Further, it can be seen from Example 3 that it is preferable that the barrier layer is formed on the surface of the resin layer on the recess portion side because the deterioration in luminance is small even without providing the barrier layer on the substrate film.

In addition, it can be seen from a comparison between Examples 1 and 4 that it is preferable that the substrate film is provided.

It can be seen from Comparative Example 1 that the deterioration in luminance was large and deterioration rapidly progressed. The reason for this is that the barrier film was bent along the organic EL device such that cracking occurred and barrier properties deteriorated.

The example in which the organic electroluminescence layer in the organic electroluminescence element is sealed with the functional film according to the embodiment of the present invention has been described. By appropriately selecting the kind thereof, the functional film according to the embodiment of the present invention is applicable to, for example, the sealing of an organic photoelectric conversion layer in an organic solar cell and can obtain an effect of suppressing deterioration in performance.

### EXPLANATION OF REFERENCES

1, 1a to 1e: functional film

2: recess portion

3: resin layer

4: substrate film

5: barrier layer

6: uneven barrier layer

7: connection portion

8: connection portion

9: support film

10 organic EL element

11: organic EL substrate

12: organic EL device

What is claimed is:

1. A functional film comprising:
a resin layer having impermeability to oxygen in which a plurality of recess portions are formed to be discretely disposed,
wherein a modulus of elasticity of the resin layer is 0.5 GPa to 10 GPa, and
an oxygen permeability of the resin layer is 10 cc/(m²·day·atm) or lower.

2. The functional film according to claim 1, further comprising:
a substrate film that is formed on a surface of the resin layer opposite a surface where the recess portions are formed.

3. The functional film according to claim 2,
wherein an oxygen permeability of the substrate film is 1 cc/(m²·day·atm) or lower.

4. The functional film according to claim 1,
wherein at least an inorganic layer is formed on the surface of the resin layer on the recess portion side.

5. The functional film according to claim 3,
wherein at least an inorganic layer is formed on the surface of the resin layer on the recess portion side.

6. An organic EL element comprising:
the functional film according to claim 1.

7. An organic EL element comprising:
the functional film according to claim 5.
